(19) United States
(12) Patent Application Publication
(10) Pub. No.: US 2007/0252190 A1
(43) Pub. Date: Nov. 1, 2007

(54) Nonvolatile memory device and method for manufacturing the same

(76) Inventors: Jae-Hyun Park, Yongin-si (KR); Chul-Soon Kwon, Seoul (KR); Jae-Min Yu, Anyang-si (KR); Ji-Woon Rim, Seoul (KR); Young-Cheon Jeong, Yongin-si (KR); In-Gu Yoon, Uiwang-si (KR); Jung-Ho Moon, Seoul (KR)

Correspondence Address: HARNESS, DICKEY & PIERCE, P.L.C., P.O. BOX 8910, RESTON, VA, 20195, US

(21) Appl. No.: 11/653,962

(22) Filed: Jan. 17, 2007

(30) Foreign Application Priority Data
Jan. 17, 2006 (KR) 10-2006-0005033

(51) Int. Cl. H01L 29/788; H01L 21/336

(52) U.S. Cl. 257/315; 438/257; 257/E29.3; 257/E21.409

(57) ABSTRACT

Provided are a nonvolatile memory device and a method for manufacturing the same. The nonvolatile memory device may include a semiconductor substrate, a floating gate, a second insulation layer, a third insulation layer, a control gate, and a common source line. The semiconductor substrate may have an active region limited by a device isolation region. The floating gate may be formed on the active region with a first insulation layer between the floating gate and the active region. The second insulation layer covers one side of the floating gate, and the third insulation layer covers the floating gate and the second insulation layer. The control gate may be formed on the other side of the floating gate with a fourth insulation layer between the control gate and the floating gate. The common source line may be formed in a portion of the substrate that is located under the second insulation layer.

### PRIORITY STATEMENT

This application claims priority under 35 USC § 119 to Korean Patent Application No. 2006-05033, filed on Jan. 17, 2006, in the Korean Intellectual Property Office (KIPO), the entire contents of which are herein incorporated by reference.

### BACKGROUND

1. Field

Example embodiments relate to a semiconductor device and a method for manufacturing the same. Other example embodiments relate to a nonvolatile memory device and a method for manufacturing the same.

2. Description of the Related Art

Semiconductor memory devices may be classified into volatile memory devices and nonvolatile memory devices. The volatile memory devices (e.g., dynamic random access memories (DRAMs) and/or static random access memories (SRAMs)) may have increased data input/output speed, but may not retain data when no power is being applied to the memory device. The nonvolatile memory devices may maintain stored data even when no power is being applied to the memory device.

Flash memory devices are higher-integration devices developed by combining erasable programmable read only memory (EPROM), which may be programmed and erased, with an electrically erasable programmable read only memory (EEPROM), which may be electrically programmed and erased. The flash memory devices are classified into floating gate type flash memories and floating trap type flash memories depending on the data storage layer constituting a unit cell. Also, the flash memory devices are classified into stacked gate type flash memory devices and split gate type flash memory devices depending on a unit cell structure.

FIG. 1 is a diagram of a conventional stacked gate type flash memory device. Referring to FIG. 1, a conventional stacked gate cell 20 may include a floating gate 24 and a control gate 28 sequentially stacked on a substrate 10. A tunnel oxide layer 22 may be interposed or inserted between the substrate 10 and the floating gate 24. A blocking oxide layer 26 may be interposed or inserted between the floating gate 24 and a control gate 28. Source and drain regions 13 and 16 may be located in portions of the substrate 10 that correspond to both sides of a stacked gate structure. The above-described stacked gate cell may perform a program operation in the drain region 16 using Channel Hot Electron Injection (CHEI) and may perform an erase operation in the source region 13 using Fowler-Nordheim (F-N) tunneling.

Because this stacked gate cell is smaller and has a higher integration, the stacked gate cell has been widely used in an initial stage of the semiconductor industry. The stacked gate cell may have an over-erasing problem. The over-erasing problem may occur when the floating gate is undesirably discharged during an erase operation of the stacked gate cell. A threshold voltage of an undesirably discharged cell may have a negative value. The above may create a current flow even when the cell is not selected (for example, a reading voltage may not be applied to a control gate). To solve this over-erase problem, two structures of cells have been introduced, e.g., a two-transistor cell and a split gate cell.

FIG. 2 is a diagram of a memory device having a conventional two-transistor cell. Referring to FIG. 2, a conventional two-transistor cell additionally may include a select transistor 30 spaced a predetermined or given distance from a conventional stacked gate cell 20. The select transistor 30 may include a select gate 38 formed on a substrate 10 with a gate insulation layer 32 interposed or inserted between the select gate 38 and the substrate 10, and source and drain regions 13 and 16 formed in portions of the substrate 10 that correspond to both sides of the select gate 38. The conventional stacked gate cell 20 may perform program and erase operations. When the cell is not selected, the select gate 38 may prevent or reduce a leakage current caused by an undesirably discharged floating gate 24. Because this two-transistor cell structure has an impurity diffusion region 16 between the stacked gate cell 20 and the select transistor 30, a relatively highly integrated memory device may be difficult to achieve.

FIG. 3 is a diagram of a conventional split gate type memory device. In the conventional split gate type memory device, a pair of memory cells 20 may share one source region 13. The source region 13 may be electrically connected with a common source line 15 located thereon. Each memory cell 20 may include a gate insulation layer 22, a floating gate 24, a tunneling insulation layer 26, and a control gate 28. Unlike a stacked gate cell, because the control gate 28 is located on a channel region 19, a portion of the channel region 19 that is located under the control gate 28 may prevent or reduce leakage current from a portion of the channel region 19 that is located under an undesirably discharged floating gate 24 when the control gate 28 is turned off.

The split gate type memory device may include an insulation spacer 32 formed on sidewalls of the floating gate 24 in order to prevent or reduce short-circuit between the floating gate 24 formed of a conductive material and the common source line 15. As illustrated in FIG. 3, there may be an increased possibility that short-circuit is generated at a portion between an oxide layer spacer 31 and the insulation spacer 32 (e.g., an edge portion of the floating gate 24). The problem may become more severe even as a memory device is relatively highly integrated. Also, because a floating gate is formed after an active region is formed through a device isolation process in the conventional art, misalignment may be generated between the floating gate and the active region. Due to such misalignment, reliability of a memory device may be reduced.

### SUMMARY

Example embodiments provide a nonvolatile memory device of a higher integration and improved reliability and a method for manufacturing the same.

According to example embodiments, a nonvolatile memory device may include a semiconductor substrate having an active region limited by a device isolation region, at least one floating gate on the active region with a first insulation layer between the floating gate and the active region, a second insulation layer on at least one side of the at least one floating gate, a third insulation layer on the at least one floating gate and the second insulation layer, at least one control gate on a side of the at least one floating gate with a fourth insulation layer between the control gate and the floating gate and a common source line in a portion of the substrate that is located under the second insulation layer, and at least one drain region formed in one side of the control gate. An upper lateral side of the at least one control gate may be self-aligned by contacting a lateral side of the third insulation layer.

According to example embodiments, a nonvolatile memory device may include a semiconductor substrate including device isolation regions that extend in a first direction, and are arranged in a second direction crossing the first direction, and active regions limited by the device isolation regions, the device isolation regions being formed of a device isolation layer that fills a trench for device isolation, memory cells arranged in the second direction and formed on the active regions, a common source line formed along a profile of the trench in a portion of the substrate that is located between adjacent memory cells in the first direction, and drain regions spaced a distance to an opposite side of the common source line by the memory cells, arranged in the second direction, and formed in the active regions.

A pair of memory cells adjacent to the common source line therebetween may be symmetric with each other. Each of the memory cells may include a floating gate on the active region with a first insulation layer between the floating gate and the active region and a control gate on a lateral side of the floating gate that faces the drain region with a second insulation layer between the control gate and the lateral side of the floating gate. The nonvolatile memory device may further include a “T”-shaped insulation layer between the memory cells adjacent to the common source line between the memory cells, and including a vertical component between the floating gates and a horizontal component on the floating gates and the vertical component, wherein an upper portion of the control gate is self-aligned by contacting the horizontal component of the “T”-shaped insulation layer. The control gate of each of the memory cells may be connected in the second direction to constitute a wordline. The common source line may include source regions in portions of active regions that are between adjacent memory cells in the first direction, and connection regions for electrically connecting the source regions, wherein the connection regions are lower than the source regions.

According to example embodiments, a method for manufacturing a nonvolatile memory device may include forming first insulation layer patterns and first conductive layer patterns on an active region limited by a device isolation region of a semiconductor substrate, forming a sacrificial layer on the semiconductor substrate, etching the sacrificial layer to form a sacrificial layer pattern having a first hole extending in a second direction, forming an insulation layer spacer on both sidewalls of the first hole, performing an etching process to remove a portion of the first conductive layer patterns, the first insulation layer patterns, and the device isolation layer that is exposed between the insulation layer spacers and to form a second hole exposing a corresponding portion of the substrate, filling the second hole and the first hole with an insulation material to form a second insulation layer and a third insulation layer, respectively, after removing the sacrificial layer patterns, removing a portion of the first conductive layer pattern that is exposed to an outside of the third insulation layer to form a self-aligned floating gate under the third insulation layer, forming a fourth insulation layer formed on sidewalls of the floating gate and forming a self-aligned control gate on a lateral side of the fourth insulation layer and the third insulation layer.

Forming the first insulation layer patterns and the first conductive layer patterns may include forming a first insulation layer and a first conductive layer on the semiconductor substrate, etching a portion of the first conductive layer, the first insulation layer, and the semiconductor substrate to form a trench for device isolation that extends to a first direction, and filling the trench with a device isolation layer to limit the active region. The method may further comprise, after forming the second hole, performing an ion implantation process on a portion of the semiconductor substrate that is exposed by the etching process to form a common source line. The common source line may be formed along a profile of the trench. The device isolation layer may have an upper surface whose height is equal to or greater than an upper surface of the first conductive layer patterns. While the sacrificial layer patterns are formed, an upper portion of the first conductive layer patterns that is exposed by the first hole may be removed.

The etching process may include etching the first conductive layer patterns, and etching the first insulation layer patterns and the device isolation layer, wherein the insulation layer spacer is simultaneously etched during the etching of the first insulation layer patterns and the device isolation layer, so that a portion of the insulation layer spacer remains on the first conductive layer patterns. The third insulation layer may include the remaining insulation layer spacer. The sacrificial layer patterns and the third insulation layer may be formed of materials having etching selectivity with respect to each other. The second insulation layer may have different thicknesses on the active region and the device isolation region. Forming the control gate may include forming a second conductive layer and an antireflection layer on the semiconductor substrate, performing a planarization process to form antireflection layer patterns exposing a portion of the second conductive layer and the third insulation layer, performing a thermal oxidation process to form oxide layer patterns on the exposed portion of the second conductive layer, and after removing the antireflection layer patterns, etching the second conductive layer using the oxide layer patterns as an etch mask.

### BRIEF DESCRIPTION OF THE DRAWINGS

Example embodiments will be more clearly understood from the following detailed description taken in conjunction with the accompanying drawings. FIGS. 1-19C represent non-limiting, example embodiments as described herein.

FIG. 1 is a diagram of a conventional stacked gate type memory device;

FIG. 2 is a diagram of a memory device having a conventional two-transistor cell;

FIG. 3 is a diagram of a conventional split gate type memory device;

FIG. 4 is a diagram of a nonvolatile memory device according to example embodiments;

FIGS. 5A to 5C are diagrams taken along lines A-A′, B-B′, and C-C′ of FIG. 4, respectively; and

FIGS. 6A to 19A, FIGS. 6B to 19B, and FIGS. 6C to 19C are diagrams taken along lines A-A, B-B′, and C-C′ of FIG. 4, respectively, explaining a method for manufacturing a nonvolatile memory device according to example embodiments.

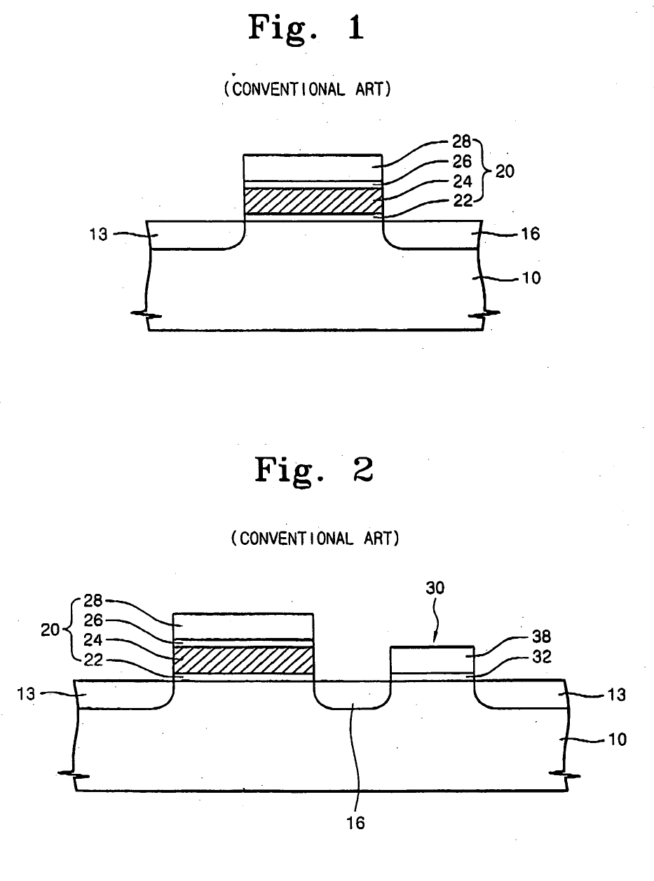

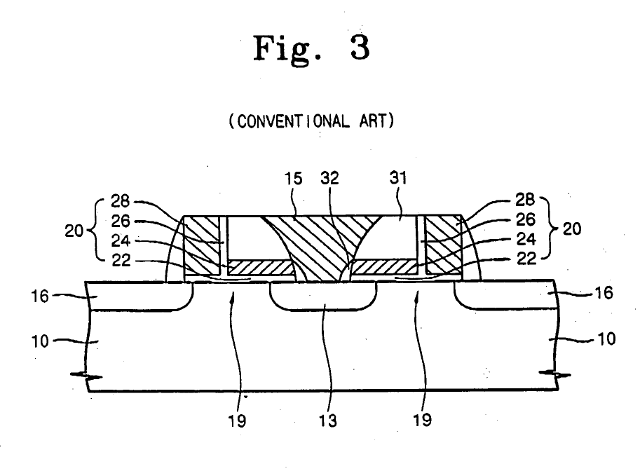

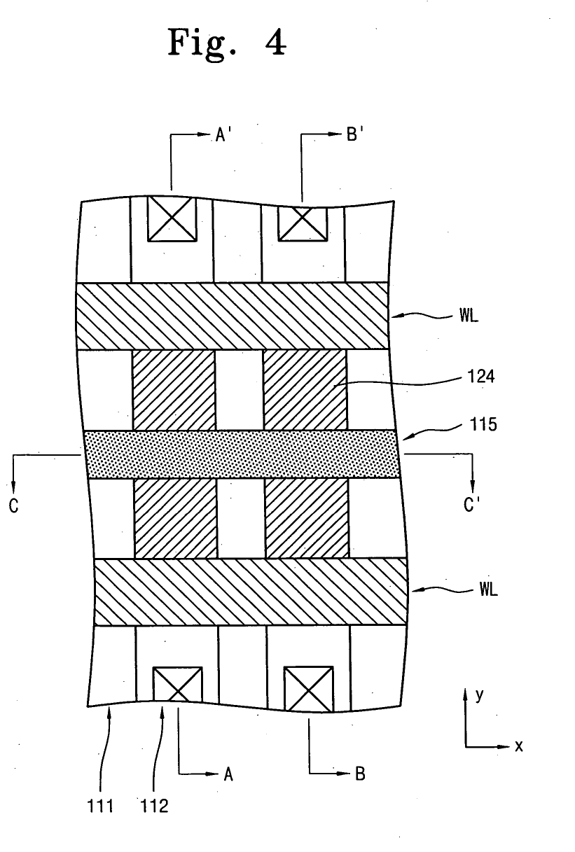

### DETAILED DESCRIPTION OF EXAMPLE EMBODIMENTS

Reference will now be made in detail to example embodiments, examples of which are illustrated in the accompanying drawings. However, example embodiments are not limited to the embodiments illustrated herein after, and the embodiments herein are rather introduced to provide complete understanding of the scope and spirit of example embodiments.

In the specification, describing a predetermined or given layer as being located on other layer or a substrate means that the predetermined or given layer may be directly on other layer or the substrate, and/or a third layer may be interposed or inserted therebetween. Also, though terms such as a first and a second are used to describe various regions and layers, these regions and layers should not be limited to these terms. These terms are used to merely distinguish them from other regions or layers. A first insulation layer described as a first member in one embodiment may be described as a second insulation layer in another embodiment. In the drawings, the size and the relative size of layers and regions are exaggerated for clarity. Like reference numerals in the drawings denote like elements throughout the specification.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

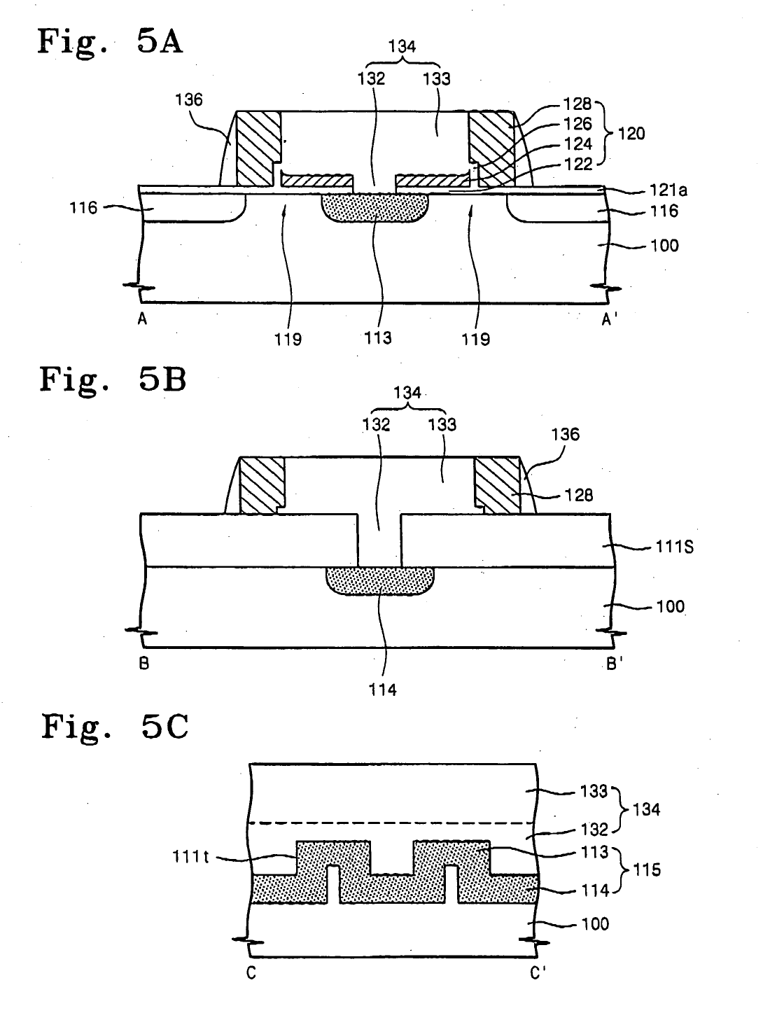

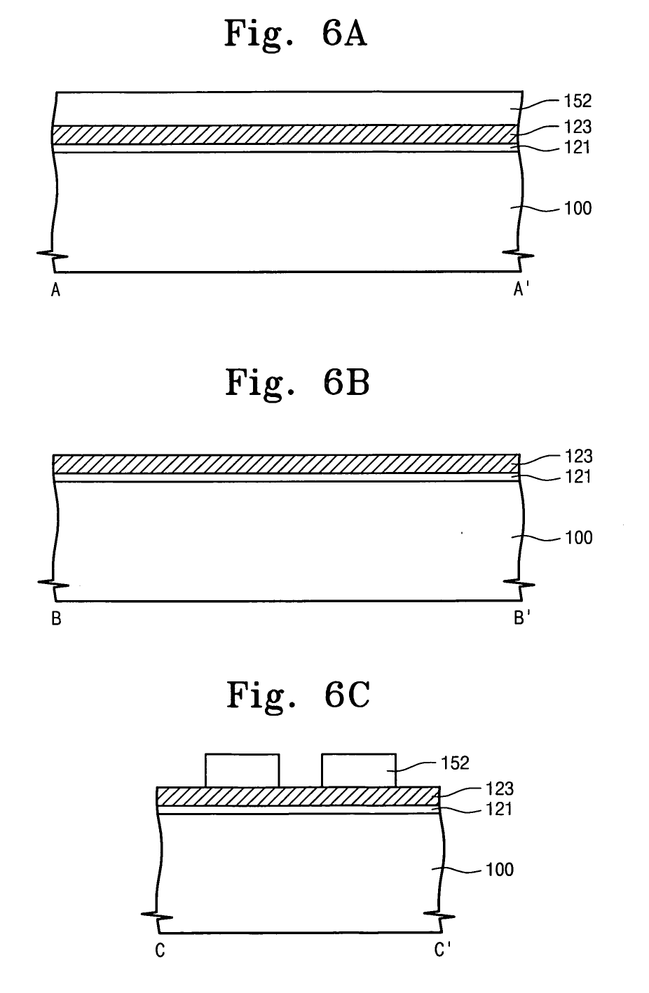

FIG. 4 is a diagram of a nonvolatile memory device according to example embodiments, and FIGS. 5A to 5C are diagrams taken along lines A-A′, B-B′, and C-C′ of FIG. 4, respectively. Referring to FIG. 4, FIGS. 5A to 5C, device isolation regions 111 may be disposed in a first direction (y-axis direction) on a semiconductor substrate 100, and active regions 112 may be disposed between the device isolation regions 111. The device isolation regions 111 may include a device isolation layer formed by a shallow trench isolation (STI) process.

Four memory cells 120 may be arranged on the active regions 112. Though FIG. 4 illustrates only four memory cells for convenience in description and simplification of the drawing, a plurality of memory cells 120 may be arranged in two-dimensionally. Each of the memory cells 120 may include a first insulation layer 122, a floating gate 124, a fourth insulation layer 126, and a control gate 128. An insulation layer 134 having a “T”-shaped cross-section may be located between the memory cells 120. The “T”-shaped insulation layer 134 may include a vertical component of a second insulation layer 132 and a horizontal component of a third insulation layer 133. The second insulation layer 132 may fill a space between floating gates 124 such that a lower surface of the second insulation layer 132 may contact a common source line 115, and an upper surface of the second insulation layer 132 may contact the third insulation layer 133. The third insulation layer 133 may cover the floating gate 124 and the second insulation layer 132.

A thickness of the second insulation layer 132 may change depending on a position of the second insulation layer 132. A thickness of the second insulation layer 132 located in the active region 112 may be equal to the sum of a thickness of the floating gate 124 (a thickness excluding a tip) and a thickness of the first insulation layer 122 (refer to FIG. 5A), but a thickness of the second insulation layer 132 located in the device isolation region 111 may be equal to a thickness of the device isolation layer 111s (refer to FIG. 5B). The “T”-shaped insulation layer 134 may be a chemical vapor deposition (CVD) oxide layer.

The common source line 115 extending to a second direction (x-axis direction) may be located between the memory cells. The common source line 115 may include a connection region 114 for electrically connecting a source region 113 and another source region 113 formed in the active regions 112. The connection region 114 may be formed along a profile of a trench 111t for device isolation. Because the common source line 115 is formed in the substrate 100 in a memory device as described above, there may be no danger that short-circuit is generated between the common source line 115 and the floating gate 124. A memory device may be relatively highly integrated and reliability of a memory device may improve.

A drain region 116 may be located in a portion of the active region 112 that is located in an outer side of the control gate 128. A channel region 119 between the source region 113 and the drain regions 116 may include a first channel region 117 located under the floating gate 124 and a second channel region 118 under the control gate 128. Unlike the stacked gate cell, because the second channel region 118 is located under the control gate 128, the second channel region 118 may prevent or reduce a leakage current from the first channel region 117 located under an undesirably discharged floating gate 124 when the control gate 128 is turned off. Also, a malfunction of the memory device may be prevented or reduced.

A portion of the first insulation layer 122 formed under the floating gate 124 (and on the first channel region) may be a thermal oxide layer and/or a CVD oxide layer. The upper portion of the first insulation layer 122 may couple a voltage applied to the source region 113 to raise an electrical potential of the floating gate 124 during a program operation. The first insulation layer 122 may be referred to as a coupling oxide layer. A charge may be injected into the floating gate 124 via the first insulation layer 122 during the program operation. A portion of the first insulation layer 122 formed under the control gate 128 (and on the second channel region) may be simultaneously formed when the portion of the first insulation layer under the floating gate 124 is formed and may be formed separately.

For example, the portion of the first insulation layer 122 formed under the control gate 128 may be formed separately when the fourth insulation layer 126 is formed. Also, the fourth insulation layer 126 formed on sidewalls of the floating gate 124 may be a thermal oxide layer and/or a CVD oxide layer. The fourth insulation layer 126 may be tunneled and may serve as a movement path of a charge during an erase operation. The fourth insulation layer 126 may be referred to as a tunneling oxide layer. Charge from the floating gate 124 may move to the control gate 128 during an erase operation.

The floating gate 124 may be located on the first channel region 117 with the first insulation layer 122 interposed or inserted between the floating gate 124 and the first channel region 117. The floating gate 124 may be self-aligned under the third insulation layer 133 and an upper surface of the floating gate 124 may be lower than an upper surface of the device isolation layer 111s. The floating gate 124 may have a sharp tip at an edge (a portion contacting the fourth insulation layer 126), by which an F-N tunneling effect may increase. The floating gate 124 may be formed of doped polysilicon. The control gate 128 may be located on the second channel region 118 with the first insulation layer 122 interposed or inserted between the control gate 128 and the second channel region 118. The control gate 128 may be self-aligned on a lateral side of the fourth insulation layer 126 and the third insulation layer 133. The control gates 128 of respective memory cells 120 may be connected in the second direction to constitute a wordline (WL). The control gate 128 may be formed of doped polysilicon. The gate spacer 136 may cover sidewalls of the control gate 128. The gate spacer 136 may be formed of a silicon nitride layer.

An operation of the above-described memory device will be briefly described below. During a program operation, an increased voltage may be applied to the source region 113, and an increased voltage may be applied to the drain region 116. A charge (a hot carrier) may be injected into the floating gate 124 from the semiconductor substrate 100 via the first insulation layer 122 formed under the floating gate 124. One of two states, for example, a program-on and/or a program-off, may be determined depending on a charge amount injected into the floating gate 124. A reading operation may be performed when a sense amplifier senses charges stored in the memory cell 120. During an erase operation for the memory cell 120, an increased voltage may be applied to the control gate 128 to allow the charges injected into the floating gate 124 to tunnel through the fourth insulation layer 126 and reach the control gate 128.

As described above, because the floating gate 128 has a tip shape (for example, an upper edge of the floating gate represents a shape profile), charge movement may be relatively rapid and a program voltage may be reduced. According to the above-described memory device, because both the floating gate 124 and the control gate 128 may be formed in a self-alignment type, an overlapping area between “control gate and substrate” may be maintained with respect to left and right cells. An overlapping area between “floating gate and control gate” may be maintained with respect to left and right cells.

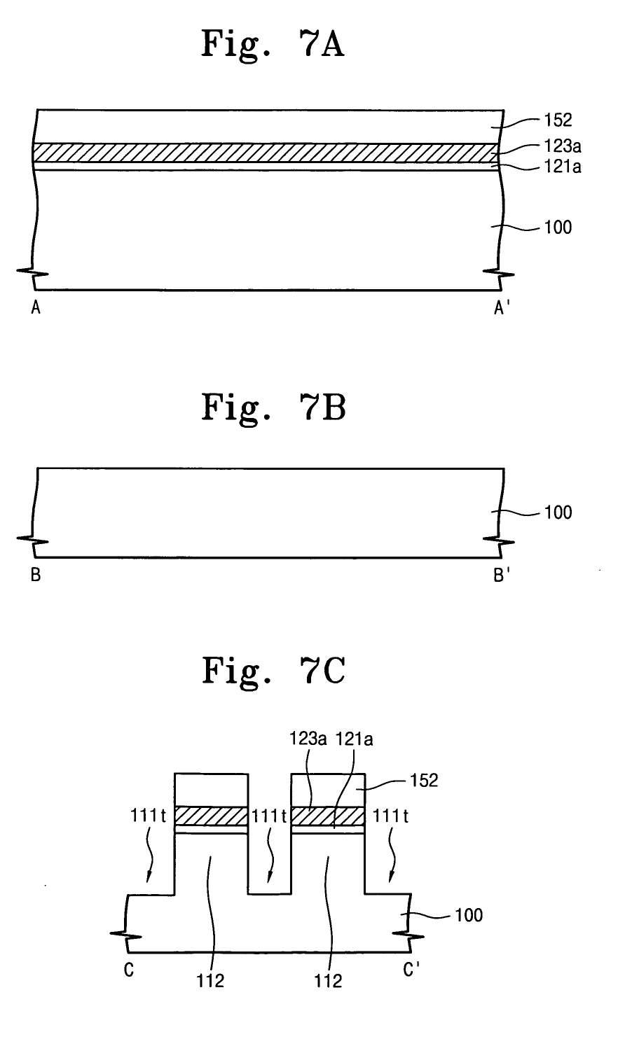

A method for forming a nonvolatile memory device will be described according to example embodiments. FIGS. 6A to 19A, FIGS. 6B to 19B, and FIGS. 6C to 19C are cross-sectional views taken along lines A-A, B-B′, and C-C′ of FIG. 4, respectively, explaining a method for manufacturing a nonvolatile memory device according to example embodiments.

Referring to FIGS. 6A to 6C, a first insulation layer 121, a first conductive layer 123, and a mask pattern 152 may be formed on a semiconductor substrate 100. The semiconductor substrate 100 may be a conventional bulk silicon substrate. Also, the semiconductor substrate 100 may be a substrate having physical, chemical, and electrical properties different from those of the bulk silicon substrate. For example, the semiconductor substrate 100 may be a substrate where an epitaxial layer of silicon and/or silicon geranium is formed on a silicon substrate using an epitaxial growth method. Also, the semiconductor substrate 100 may be a silicon-on-insulator (SOI) substrate where a semiconductor layer is formed on an insulation layer.

The first insulation layer 121 may be a silicon oxide layer formed of a well-known thin film forming process (e.g., a thermal oxidation process and/or a chemical vapor deposition (CVD) process). The first conductive layer 123 may be formed of doped polysilicon through the well-known thin film forming process. The first conductive layer 123 may be formed to provide a floating gate. The mask pattern 152 may be formed of a silicon nitride layer using a conventional thin film forming process, photolithography, and/or a conventional etching process. The mask pattern 152 may correspond to an active region to be formed later. Portions covered by the mask pattern 152 may become active regions, and portions exposed through the mask pattern 152 may become device isolation regions. During the photolithography, an antireflection layer, e.g., a silicon oxide nitride layer, may be further formed on the mask pattern 152 in order to prevent or reduce diffuse reflection.

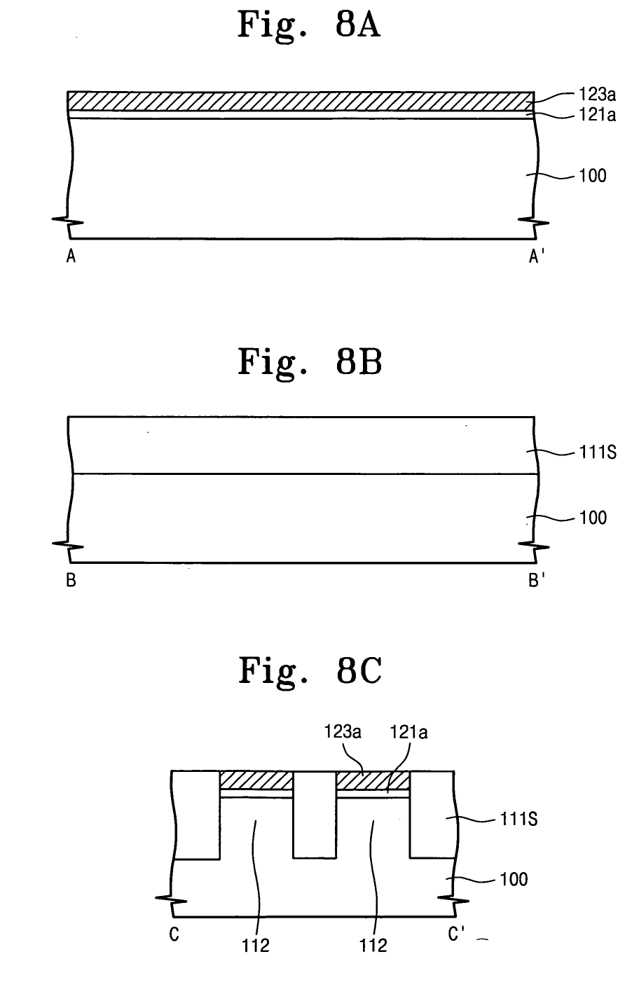

Referring to FIGS. 7A to 7C, trenches 111t for device isolation may be formed by etching a portion of the first conductive layer 123, the first insulation layer 121, and the substrate 100 using the mask pattern for an etch mask. Anisotropic dry etching may be used. As described above, in example embodiments, a device isolation process may be performed using a self-alignment trench separation technology. First conductive layer patterns 123a and first insulation layer patterns 121a may remain under the mask pattern 152, for example, on only active regions 112. Trenches 111t may extend in a first direction and may be arranged vertically in the semiconductor substrate 100.

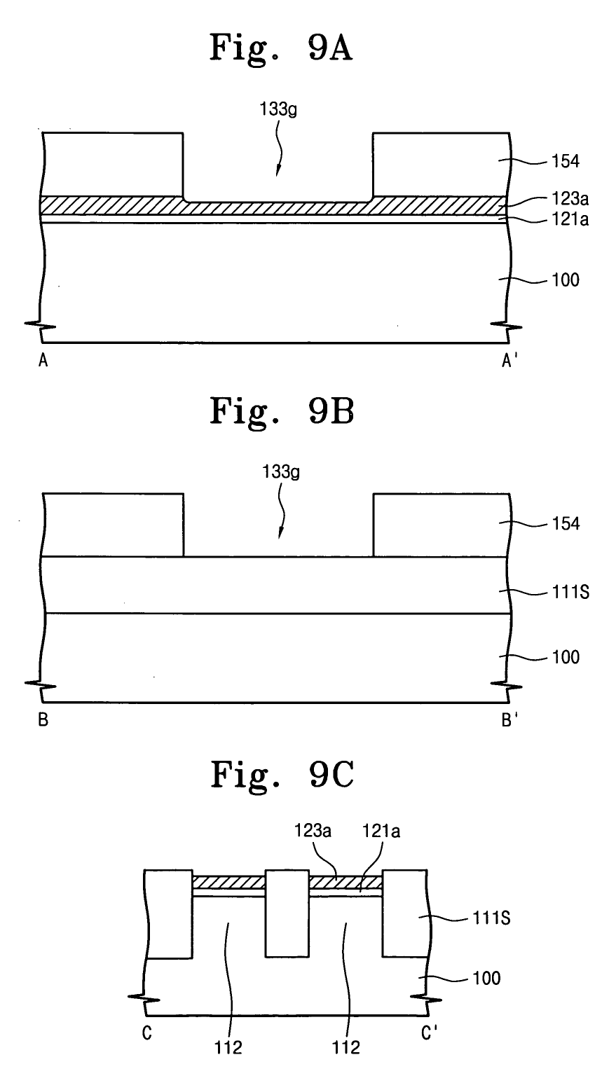

Referring to FIGS. 8A to 8C, device isolation layers 111s may be formed by filling the trenches 111t with an insulation material, and performing a planarization process. The device isolation layer 111s may be formed using a two-step process including a thin film forming process and a planarization process. The thin film forming process may be a high-density plasma CVD process, and the planarization process may be chemical mechanical planarization process. The mask pattern 152 may be removed using phosphoric acid before the planarization process is performed, or may be removed by the planarization process. The planarization process may be performed until an upper surface of the first conductive layer patterns 123a is exposed. The first insulation layer patterns 121a may remain under the first conductive layer patterns 123a on active regions 112.

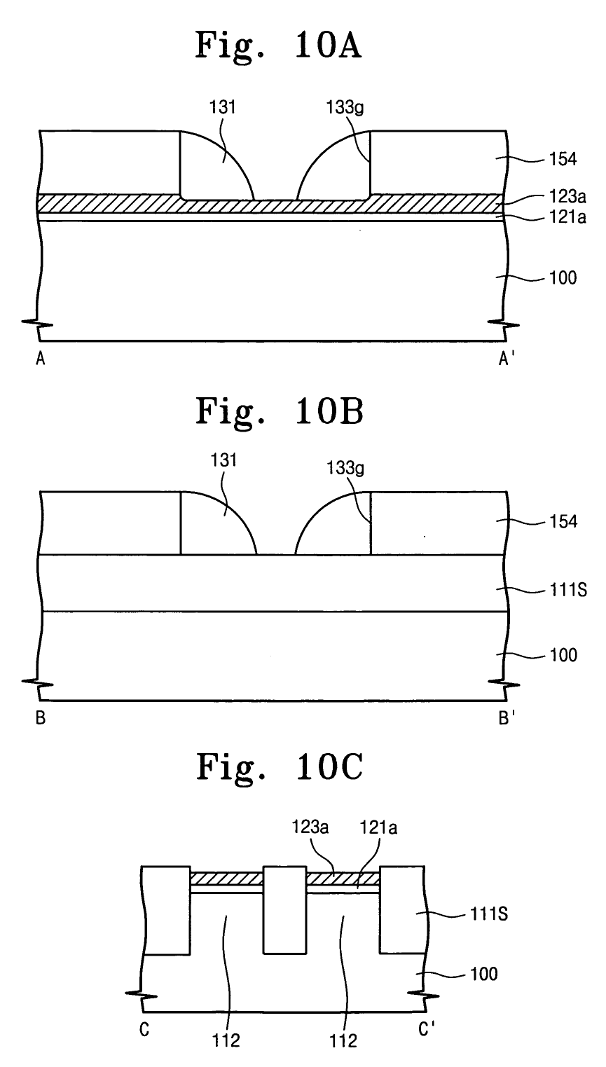

Referring to FIGS. 9A to 9C, a sacrificial layer pattern 154 having a first hole 133g may be formed on the substrate 100. The sacrificial layer pattern 154 may be formed by forming a sacrificial layer on an entire surface of the substrate using a thin film forming process, and performing photolithography and an etching process on the sacrificial layer. The sacrificial layer pattern 154 may be formed of a silicon nitride layer. During the photolithography, an antireflection layer (not shown), e.g., a silicon oxide nitride layer, may be further formed on the sacrificial layer in order to prevent or reduce diffuse reflection.

The etching process for forming the first hole 133g may include an anisotropic etching operation for etching a sacrificial layer and isotropic etching operation for forming a concave portion in an upper surface of the first conductive pattern 123a. An edge (e.g., a region adjacent to sidewalls of the sacrificial layer pattern 154) of the concave portion may have a rounded shape. The rounded edge of the concave portion may allow a tip of a floating gate to be formed during a subsequent process. An upper surface of the first conductive layer pattern 123a that is exposed through the first hole 133g may be lower than an upper surface of the device isolation layer 111s. The first insulation layer patterns 121a may remain under the first conductive layer patterns 123a on active regions 112.

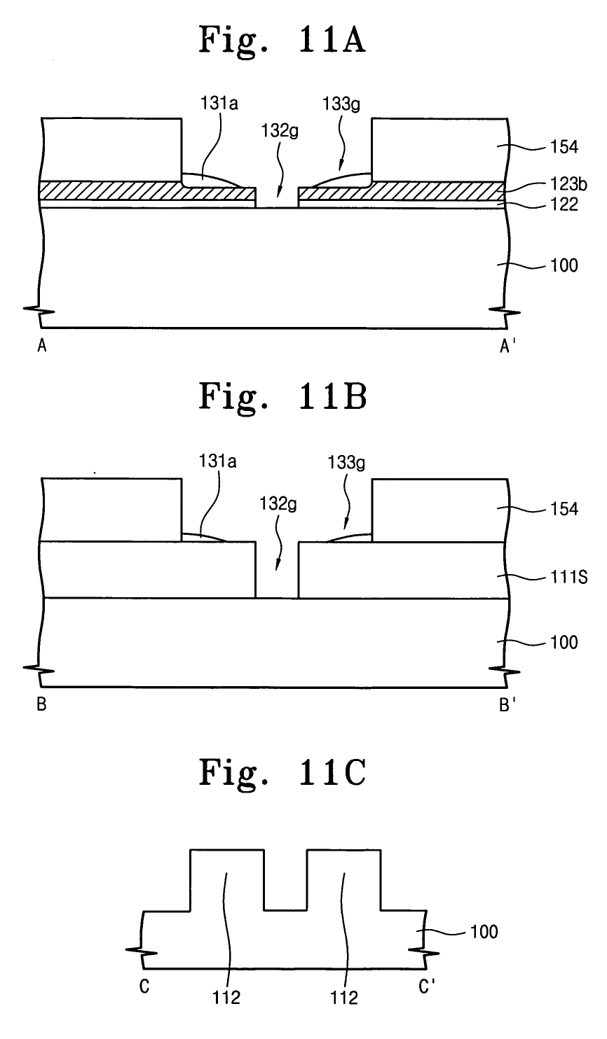

Referring to FIGS. 10A to 10C, an insulation layer spacer 131 covering sidewalls of the sacrificial layer pattern 154 may be formed. The insulation layer spacer 131 may be formed by forming an insulation layer on an entire surface of the substrate and then performing an etch-back process. The insulation layer spacer 131 may be formed of a material having etching selectivity with respect to the sacrificial layer pattern 154. For example, when the sacrificial layer pattern 154 is formed of a silicon nitride layer, the insulation layer spacer 131 may be formed of a silicon oxide layer.

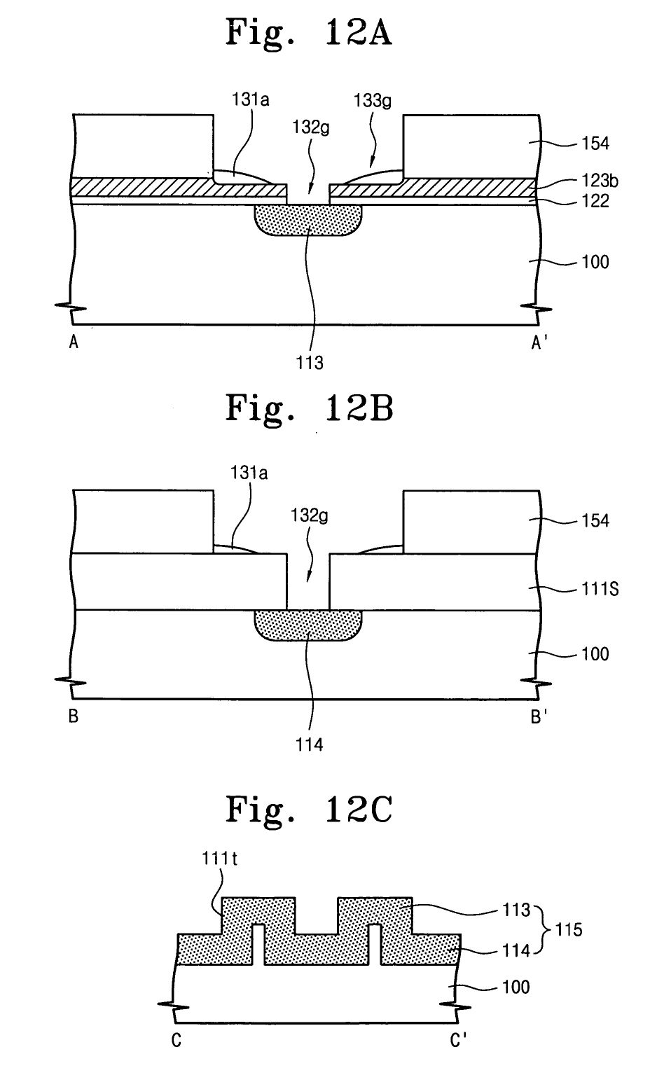

Referring to FIGS. 11A to 11C, a portion of the first conductive layer pattern 123a, exposed between insulation layer spacers 131, may be etched using the insulation layer spacer 131 for an etch mask to expose a portion of the first insulation layer pattern 121a. Subsequently, a portion of the first insulation layer pattern 121a and the device isolation layer 111s, exposed between first conductive layer patterns 123b, may be etched using the sacrificial layer pattern 154 for an etch mask to expose the substrate 100 and form a second hole 132g. An etching process for forming the second hole 132g may be anisotropic dry etching, and may include a first operation of etching the first conductive layer pattern 123a and a second operation of etching the first insulation layer pattern 121a and the device isolation layer 111s. An appropriate etching gas may be selected during each operation. For example, during the first operation, an etching gas having increased etching selectivity with respect to polysilicon may be selected. During the second operation, an etching gas having increased etching selectivity with respect to a silicon oxide layer may be selected. When the first insulation layer pattern 121a and the device isolation layer 111s are etched during the second operation, the insulation layer spacer 131 may be simultaneously etched. After the second hole 132g is formed, a residual layer 131a of the insulation layer spacer may be left on a portion of the first conductive layer pattern 123b inside the first hole 133g.

The second hole 132g may have a different depth depending on its position. Referring to FIGS. 11A and 11B again, a depth of the second hole 132g, located in the active region 112, may be a sum of a thickness of a portion of the first conductive layer pattern 123b whose upper surface is recessed and a thickness of the first insulation layer 122. A depth of the second hole 132g, located in the device isolation region, may be equal to a thickness of the device isolation layer 111s. The second hole 132g may be formed deeper in the device isolation region.

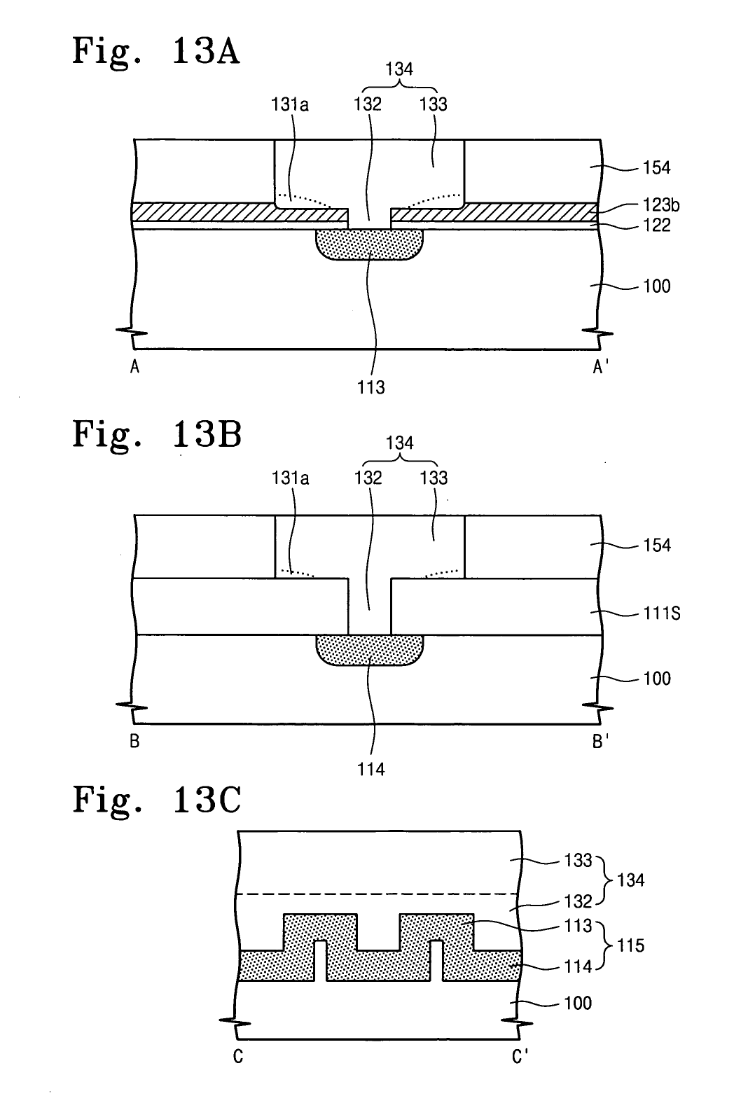

Referring to FIGS. 12A to 12C, a common source line 115 may be formed by performing an ion implantation process on a portion of the substrate 100 that is exposed through the second hole 132g. Implanted impurity ions may have a predetermined or given conductive type, for example, the implanted impurity ions may be p-type boron ions and/or n-type phosphorous ions or arsenic ions. Phosphorous ions having a rapid diffusion speed may be desirable to implant. The common source line 115 may include a connection region 114 for electrically connecting the source region 113 with other source regions formed in the active regions. The common source line 115 may be formed along a lower profile of the trench 111t of device isolation. Because the implanted ions diffuse inside the substrate 100, a width of the common source line 115 may be wider than that of the second hole 132g.

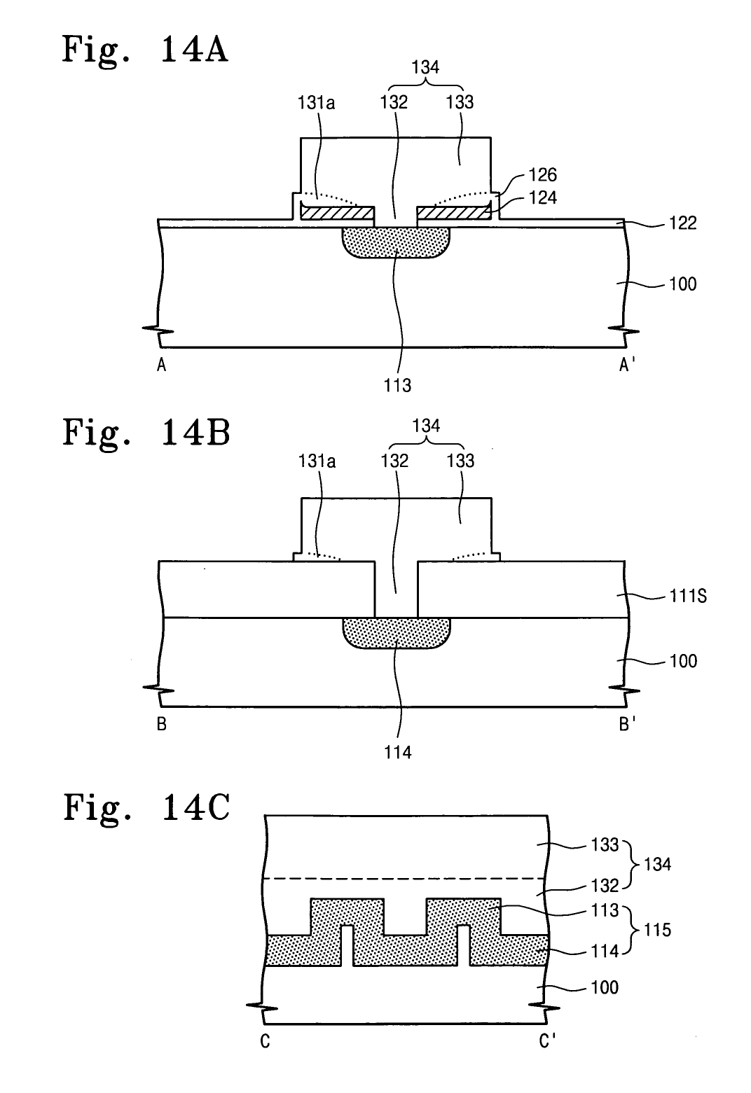

Referring to FIGS. 13A to 13C, a “T”-shaped insulation layer 134 may be formed by filling the second hole 132g and the first hole 133g with an insulation material. The “T”-shaped insulation layer 134 may include a vertical component of a second insulation layer 132 and a horizontal component of a third insulation layer 133. The second insulation layer 132 may correspond to the second hole 132g and the third insulation layer 133 may correspond to the first hole 133g. The third insulation layer 133 may include a residual layer 131a of the insulation layer spacer. The “T”-shaped insulation layer 134 may be formed using a well-known thin film forming process (e.g., a CVD deposition process) and a planarization process. The “T”-shaped insulation layer 134 may be formed of a material having etching selectivity with respect to the sacrificial layer patterns 154. For example, when the sacrificial layer patterns 154 are formed of a silicon nitride layer, the “T”-shaped insulation layer spacer 134 may be formed of a silicon oxide.

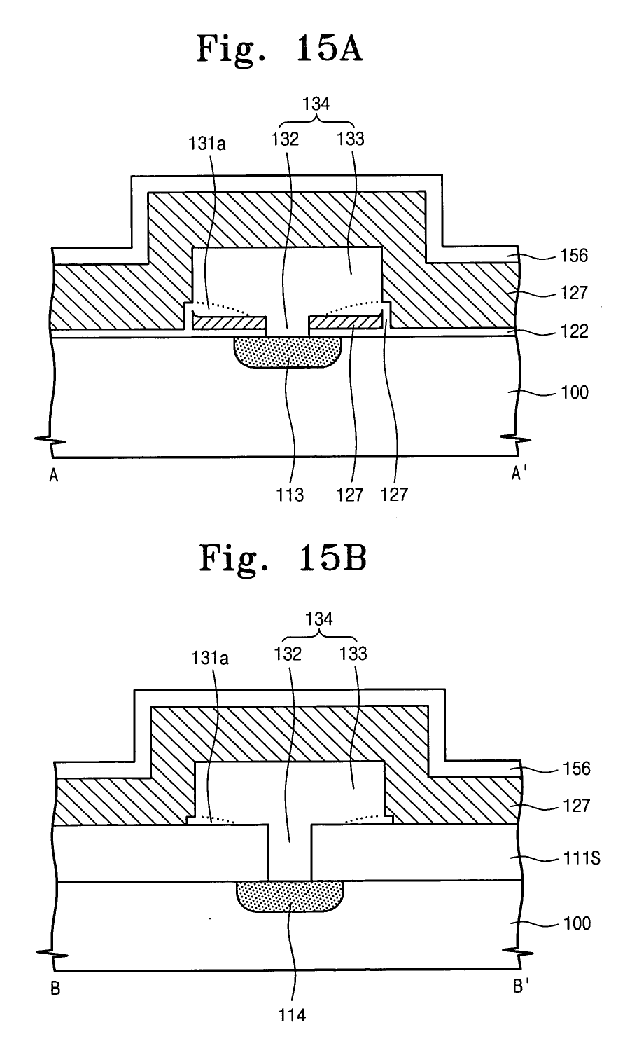

Referring to FIGS. 14A to 14C, a portion of the first conductive layer pattern 123b, exposed after removal of the sacrificial layer patterns 154, may be removed to form a floating gate 124. The sacrificial layer patterns 154 may be removed through a wet etching process using phosphoric acid solution, and the exposed portion of the first conductive layer pattern 123b may be removed through a dry etching process. The floating gate 124 may be self-aligned under the third insulation layer 133, and a tip may be formed at an edge of the floating gate 124. An operation characteristic of a memory device may be improved by the tip. Subsequently, a fourth insulation layer 126 may be formed on sidewalls of the floating gate 124. The fourth insulation layer 126 may be formed of a well-known thin film forming process (e.g., a thermal oxidation process and/or a CVD process). The floating gate 124 may be surrounded by the first, second, third, and fourth insulation layer 122, 132, 133, and 126, insulating the floating gate 124 and the common source line 115 adjacent thereto.

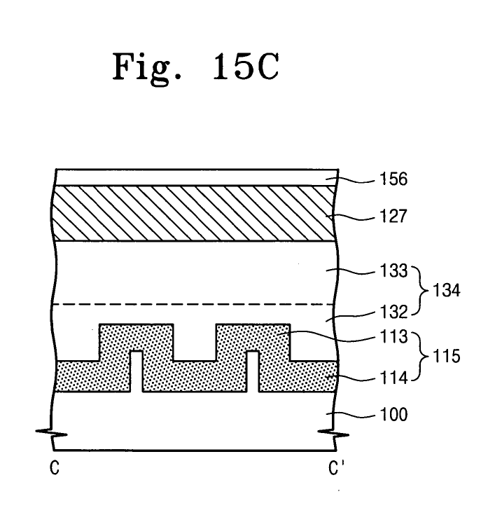

Referring to FIGS. 15A to 15C, a second conductive layer 127 and an antireflection layer 156 may be formed. The second conductive layer 127 may be formed of doped silicon using a well-known thin film forming process. The second conductive layer 127 may be formed to provide a control gate. The antireflection layer 156 may be formed of a silicon nitride layer and/or a silicon oxide nitride layer using a well-known thin film forming process. The second conductive layer 127 and the antireflection layer 156 may have a height difference caused by the third insulation layer 133.

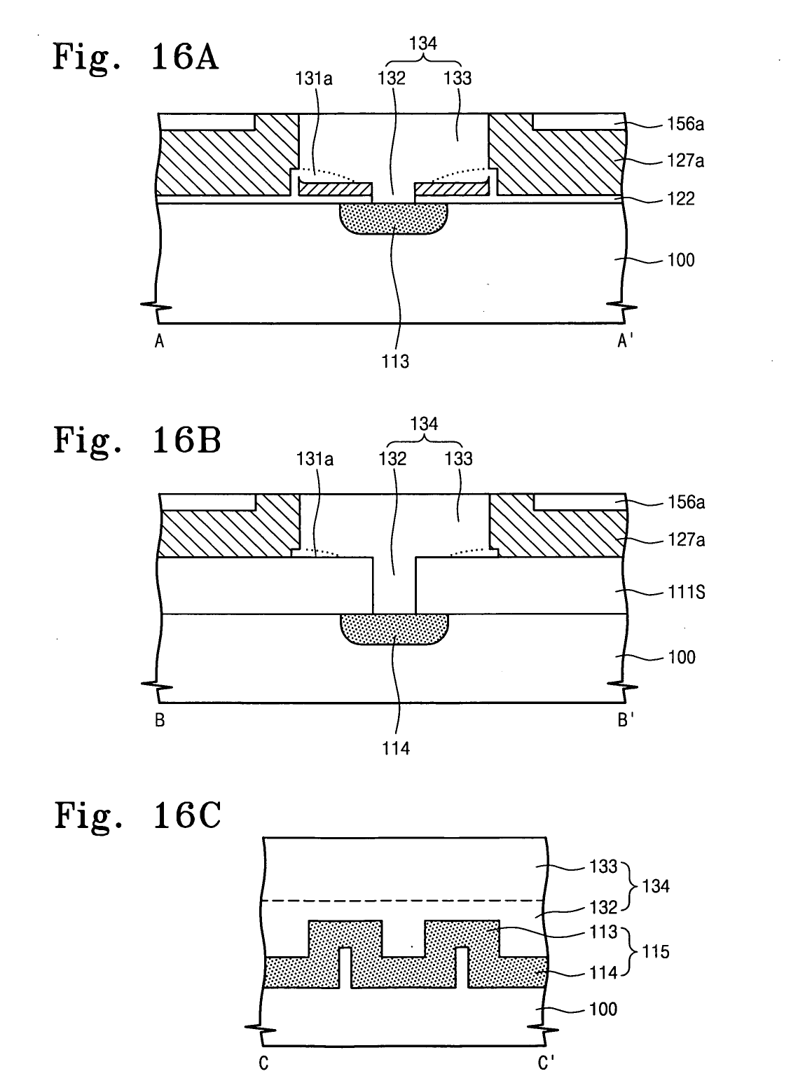

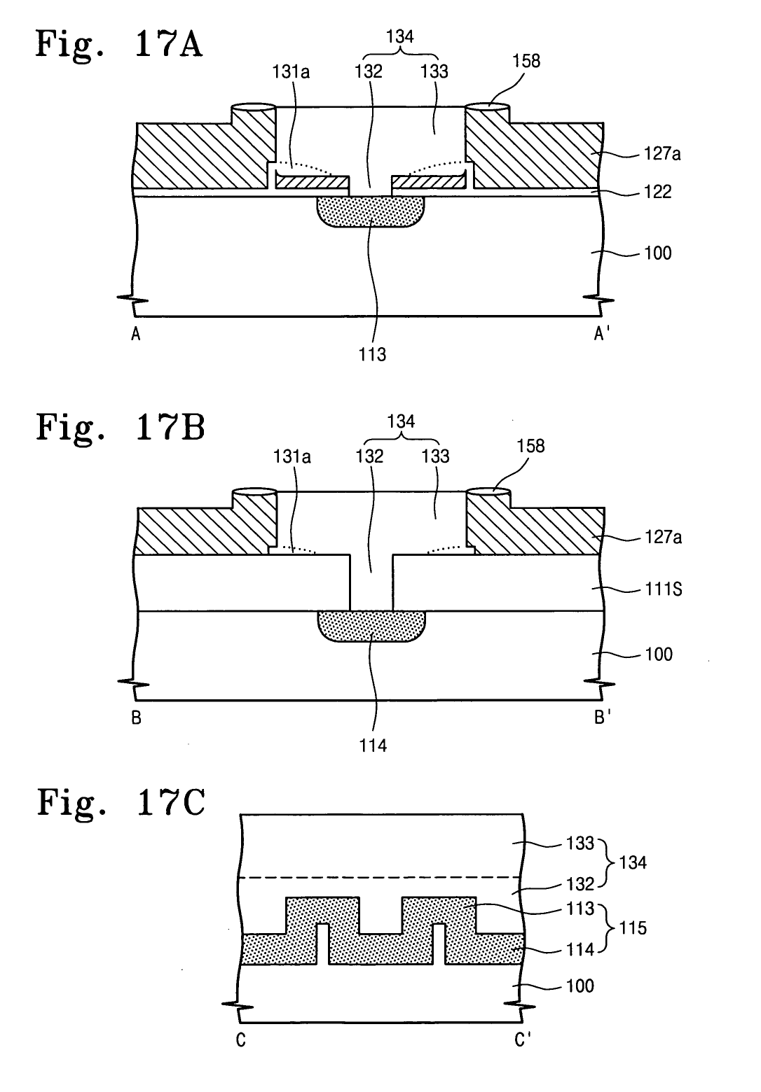

Referring to FIGS. 16A to 16C, a planarization process may be performed until the third insulation layer 133 is exposed. The second conductive layer pattern 127a may be exposed between the third insulation layer 133 and the antireflection layer pattern 156a. Because the second conductive layer 127a pattern and the antireflection layer pattern 156a are uniformly formed on an entire surface of the substrate 100, a width of an exposed portion of the second conductive layer pattern 127a may be uniform. A control gate may be formed to have a uniform width as described below. Referring to FIGS. 17A to 17C, an oxide layer mask 158 may be formed on a portion of the second conductive layer pattern 127a that is exposed through a thermal oxidation process. Subsequently, the antireflection layer pattern 156a may be removed using a phosphoric acid solution.

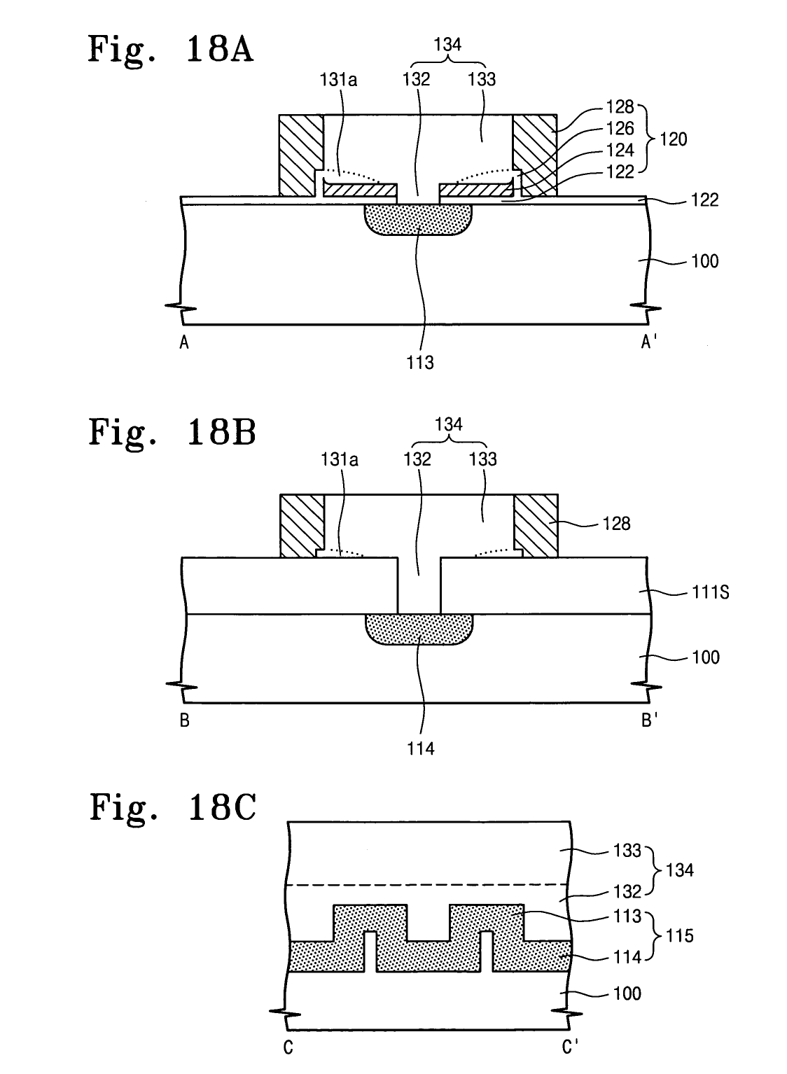

Referring to FIGS. 18A to 18C, the exposed portion of the second conductive layer pattern 127a may be etched using the oxide layer mask 158 for an etch mask to form a control gate 128. The oxide layer mask 158 used for an etch mask may be mostly consumed while the control gate 128 is formed, and the oxide layer mask 158 may be completely removed during a subsequent cleaning process. The control gate 128 may be formed to be self-aligned on a lateral side of the fourth insulation layer 126 and the third insulation layer 133.

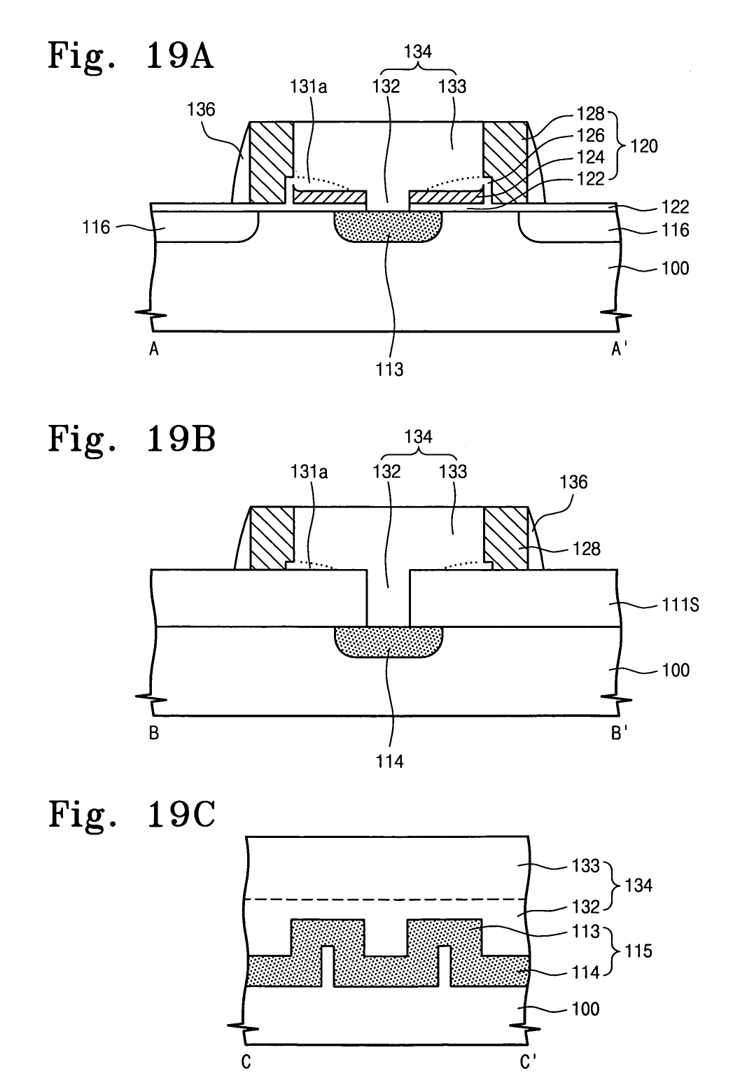

Referring to FIGS. 19A to 19C, a drain region 116 may be formed in an active region outside the control gate 128 by performing an ion implantation process. Subsequently, a gate spacer 136 may be formed by performing an etch back process after forming an insulation layer on an entire surface of the substrate. The gate spacer 136 may be formed of a silicon nitride layer.

According to example embodiments, a floating gate and a control gate may be self-aligned. Because a common source line is formed in a substrate, there may be no danger that short-circuit is generated between the floating gate and the common source line. A memory device may be relatively highly integrated, and reliability of a memory device may improve.

It will be apparent to those skilled in the art that various modifications and variations may be made in example embodiments. Thus, it may be intended that example embodiments cover the modifications and variations of example embodiments provided they come within the scope of the appended claims and their equivalents.

What is claimed is:

1. A nonvolatile memory device comprising:
a semiconductor substrate having an active region limited by a device isolation region;
at least one floating gate on the active region with a first insulation layer between the floating gate and the active region;
a second insulation layer on at least one side of the at least one floating gate;
a third insulation layer on the at least one floating gate and the second insulation layer;
at least one control gate on a side of the at least one floating gate with a fourth insulation layer between the control gate and the floating gate; and
a common source line in a portion of the substrate that is located under the second insulation layer, and at least one drain region formed in one side of the control gate.

2. The nonvolatile memory device of claim 1, wherein an upper lateral side of the at least one control gate is self-aligned by contacting a lateral side of the third insulation layer.

3. A nonvolatile memory device comprising:
a semiconductor substrate including device isolation regions that extend in a first direction, and are arranged in a second direction crossing the first direction, and active regions limited by the device isolation regions, the device isolation regions being formed of a device isolation layer that fills a trench for device isolation;
memory cells arranged in the second direction and formed on the active regions;
a common source line formed along a profile of the trench in a portion of the substrate that is located between adjacent memory cells in the first direction; and
drain regions spaced a distance to an opposite side of the common source line by the memory cells, arranged in the second direction, and formed in the active regions.

4. The nonvolatile memory device of claim 3, wherein a pair of memory cells adjacent to the common source line therebetween are symmetric with each other.

5. The nonvolatile memory device of claim 3, wherein each of the memory cells comprises:
a floating gate on the active region with a first insulation layer between the floating gate and the active region; and
a control gate on a lateral side of the floating gate that faces the drain region with a second insulation layer between the control gate and the lateral side of the floating gate.

6. The nonvolatile memory device of claim 5, further comprising:
a “T”-shaped insulation layer between the memory cells adjacent to the common source line between the memory cells, and including a vertical component between the floating gates and a horizontal component on the floating gates and the vertical component,
wherein an upper portion of the control gate is self-aligned by contacting the horizontal component of the “T”-shaped insulation layer.

7. The nonvolatile memory device of claim 5, wherein the control gate of each of the memory cells are connected in the second direction to constitute a wordline.

8. The nonvolatile memory device of claim 3, wherein the common source line includes source regions in portions of active regions that are between adjacent memory cells in the first direction, and connection regions for electrically connecting the source regions,
wherein the connection regions are lower than the source regions.

9. A method for manufacturing a nonvolatile memory device, the method comprising:
forming first insulation layer patterns and first conductive layer patterns on an active region limited by a device isolation region of a semiconductor substrate;
forming a sacrificial layer on the semiconductor substrate;
etching the sacrificial layer to form a sacrificial layer pattern having a first hole extending in a second direction;
forming an insulation layer spacer on both sidewalls of the first hole;
performing an etching process to remove a portion of the first conductive layer patterns, the first insulation layer patterns, and the device isolation layer that is exposed between the insulation layer spacers and to form a second hole exposing a corresponding portion of the substrate;
filling the second hole and the first hole with an insulation material to form a second insulation layer and a third insulation layer, respectively;
after removing the sacrificial layer patterns, removing a portion of the first conductive layer pattern that is exposed to an outside of the third insulation layer to form a self-aligned floating gate under the third insulation layer;
forming a fourth insulation layer formed on sidewalls of the floating gate; and
forming a self-aligned control gate on a lateral side of the fourth insulation layer and the third insulation layer.

10. The method of claim 9, wherein forming the first insulation layer patterns and the first conductive layer patterns comprises:
forming a first insulation layer and a first conductive layer on the semiconductor substrate;
etching a portion of the first conductive layer, the first insulation layer, and the semiconductor substrate to form a trench for device isolation that extends to a first direction; and
filling the trench with a device isolation layer to limit the active region.

11. The method of claim 10, further comprising, after forming the second hole:
performing an ion implantation process on a portion of the semiconductor substrate that is exposed by the etching process to form a common source line.

12. The method of claim 11, wherein the common source line is formed along a profile of the trench.

13. The method of claim 10, wherein the device isolation layer has an upper surface whose height is equal to or greater than an upper surface of the first conductive layer patterns.

14. The method of claim 9, wherein, while the sacrificial layer patterns are formed, an upper portion of the first conductive layer patterns that is exposed by the first hole is removed.

15. The method of claim 9, wherein the etching process comprises:
etching the first conductive layer patterns; and
etching the first insulation layer patterns and the device isolation layer,
wherein the insulation layer spacer is simultaneously etched during the etching of the first insulation layer patterns and the device isolation layer, so that a portion of the insulation layer spacer remains on the first conductive layer patterns.

16. The method of claim 15, wherein the third insulation layer includes the remaining insulation layer spacer.

17. The method of claim 9, wherein the sacrificial layer patterns and the third insulation layer are formed of materials having etching selectivity with respect to each other.

18. The method of claim 9, wherein the second insulation layer has different thicknesses on the active region and the device isolation region.

19. The method of claim 9, wherein forming the control gate comprises:
forming a second conductive layer and an antireflection layer on the semiconductor substrate;
performing a planarization process to form antireflection layer patterns exposing a portion of the second conductive layer and the third insulation layer;
performing a thermal oxidation process to form oxide layer patterns on the exposed portion of the second conductive layer; and
after removing the antireflection layer patterns, etching the second conductive layer using the oxide layer patterns as an etch mask.
